(19) United States
(12) Patent Application Publication
(10) Pub. No.: US 2013/0306127 A1
(43) Pub. Date: Nov. 21, 2013

(54) NEW SOLAR CONCENTRATION DEVICES

(71) Applicants: Jochen Ackermann, Muehltal (DE); Uwe Numrich, Gross-Zimmern (DE); Grant B. Lafontaine, Lafayette, NJ (US); Michael Thomas Pasierb, Sanford, ME (US); Andrew J. Baumler, Kennebunk, ME (US)

(72) Inventors: Jochen Ackermann, Muehltal (DE); Uwe Numrich, Gross-Zimmern (DE); Grant B. Lafontaine, Lafayette, NJ (US); Michael Thomas Pasierb, Sanford, ME (US); Andrew J. Baumler, Kennebunk, ME (US)

(73) Assignee: Evonik Roehm GmbH, Darmstadt (DE)

(21) Appl. No.: 13/981,755

(22) PCT Filed: Dec. 13, 2011
(86) PCT No.: PCT/EP11/72561

§ 371 Date: Jul. 25, 2013

Related U.S. Application Data
(60) Provisional application No. 61/437,170, filed on Jan. 28, 2011.

(30) Foreign Application Priority Data
Jan. 28, 2011 (EP) 11152497.1

(51) Int. Cl. G02B 19/00; H01L 35/02; H01L 31/0232

(52) U.S. Cl. CPC G02B 19/0014; H01L 31/0232; H01L 35/02; G02B 19/0042
USPC 136/242; 136/259; 438/72; 438/54; 359/355; 156/244.11

(57) ABSTRACT

The present invention relates to laminated solar concentration devices and to the production thereof from polymeric materials. The inventive solar concentration devices can be employed in photovoltaic systems or in solar thermal energy systems. The inventive solar concentration devices comprise Fresnel lenses and enable the efficient concentration of solar radiation onto objects such as solar cells or absorber units, irrespective of the geometry thereof. This relates, for example, to the area of a high-performance solar cell as used in concentrated photovoltaics (CPV), and equally to absorbers which are used in concentrated solar thermal energy systems (CSP). The invention in particular relates to the use of an UV- and weathering-stabilizer package for said laminated solar concentration devices, for improving optical lifetime and weathering resistance, and for preventing delamination. The invention further relates to a surface finish relevant to scratch resistance, antisoil properties, anti-reflection properties and chemicals resistance of the solar concentration device.

### FIELD OF THE INVENTION

The present invention relates to laminated solar concentration devices and to the production thereof from polymeric materials. The inventive solar concentration devices can be employed in photovoltaic systems or in solar thermal energy systems.

The inventive solar concentration devices comprise Fresnel lenses and enable the efficient concentration of solar radiation onto objects such as solar cells or absorber units, irrespective of the geometry thereof. This relates, for example, to the area of a high-performance solar cell as used in concentrated photovoltaics (CPV), and equally to absorbers which are used in concentrated solar thermal energy systems (CSP).

The invention in particular relates to the use of an UV- and weathering-stabilizer package for said laminated solar concentration devices, for improving optical lifetime and weathering resistance, and for preventing delamination. The invention further relates to a surface finish relevant to scratch resistance, antisoil properties, anti-reflection properties and chemicals resistance of the solar concentration device.

### STATE OF THE ART

Fresnel lenses have been around since the 1800's and have been used in projection TVs, overhead projectors, automobile headlamps, lighthouses and the like. Recently, Fresnel lenses have been used to focus solar energy on photovoltaic solar receivers that convert the energy into electricity.

To improve the properties of a film embossed with optical elements, such as rigidity, weather resistance and abrasion resistance, it is desirable to laminate the embossed film to a support film. Normally a thin support film is sufficient for most of the purposes. However, when a Fresnel lens is used in a solar concentrator, it is desirable to laminate the Fresnel film to a thick sheet substrate in order to increase the rigidity of the Fresnel lens, so that it can be easily installed in the solar concentrator.

Thermal lamination has been proposed as a preferred method for making laminated Fresnel lenses. Off-line thermal lamination can be performed with thin films, but is problematic for thick films like Fresnel films. This is because thermally bonding a Fresnel film to a thick sheet requires a large amount of heat and this heat normally destroys the optical structures.

On-line lamination methods as disclosed in U.S. Pat. No. 5,945,042 and U.S. Pat. No. 6,375,776 work well with thin embossed films and thin carrier films. Patent '042 specifically discloses that the embossed films have a thickness in the range of 10 to 100 μm and the thickness of the carrier films is generally in the range of 35 to 150 μm.

On-line production of thick embossed sheets, such as Fresnel lenses with acrylic substrates have been disclosed in Benz, U.S. Pat. No. 5,656,209. Benz '209 describes a process for the manufacture of linear Fresnel lenses using a three roll polishing stack designed for coextrusion of a high viscosity moulding compound and a low viscosity moulding compound. This patent is incorporated herein by its entirety. While Benz '209 provides an on-line process to manufacture Fresnel lenses, the lenses produced by this process have been found to be less sharp at the edges.

WO 2009/121708 on the other hand describes a process for thermal lamination of a film with embossed optical structures to a polymer sheet without damaging the integrity of the embossed structure.

While most of the processes in the prior art are focussed on lamination processes and qualities of the Fresnel lense structure, no sufficient solution for improving optical lifetime and weathering resistance, and for preventing delamination has been found, yet.

### Problem

The object of the present invention was to provide novel solar concentration devices for use in systems with photovoltaic uses (CPV) or with solar thermal energy uses (CSP). The disadvantages of known solar concentration devices as described above should be avoided or at least minimized.

The new concentrator should preferably have a lifetime of at least 10 years and an improved stability to environ-mental influences compared to the prior art. In a specific problem the term of use should be at least 20 years under desert conditions.

It was a further object of the present invention to provide a very simple production process which, compared to the prior art, can be performed in a less expensive, more energy-efficient, simple and rapid manner, and demands less complex logistics.

Further objects which are not stated explicitly are evident from the overall context of the description, claims and examples which follow.

### Solution

Surprisingly, it has now been found, that use of a special UV protection package in a carrier layer of a laminated Fresnel lens and/or in an UV-protection layer applied to a laminated Fresnel lens helps to avoid the described disadvantages of existing concentrator designs.

The inventive laminated solar concentration device as well as the inventive solar devices as further defined in the claims, description and examples of the present invention show an improved weather resistance.

The mechanical properties of the inventive solar concentration devices are very good over the whole period of use, i.e. reduction of the molecular mass during use is minimized and the degradation or loss of impact modifiers from polymeric layers are minimized or avoided.

The inventive laminated solar concentration devices exhibit a very good heat resistance which helps to improve the efficiency of the inventive solar devices.

Compared to coextruded Fresnel lenses as disclosed in U.S. Pat. No. 5,656,209 the surface quality of the Fresnel structure is much better which further improves the efficiency of the devices according to the invention.

Furthermore, the novel inventive concentrator has the following properties, in combination as an advantage over the prior art, particularly with regard to optical properties: the components of the inventive concentrator are particularly colour-neutral and do not become cloudy under the influence of moisture. The concentrator additionally exhibits outstanding weathering resistance and, in the case of optional finishing, very good chemical resistance, for example toward all commercial cleaning compositions. These aspects too contribute to maintaining solar concentration over a long period. In order to facilitate cleaning, the surface may have soil-repellent properties. In addition, the surface is optionally abrasion-resistant and/or scratch-resistant.

The process of the present invention allows a continuous production of the inventive Fresnel lenses and is very flexible in view of the layer structure or layer thicknesses of the inventive laminates. As a result significant economical advantages have been achieved. Subject of the present invention are therefore UV protected laminated solar concentration devices, characterized in that, the devices, viewed from the direction of the light source, consists of at least the following layers:
a polymeric carrier layer (3)
a polymeric film (1) having a first surface embossed with optical structures which form one or more Fresnel lens(es) and having a second surface which is bonded to the carrier layer (3) either directly or via an adhesive layer (2)
   wherein
the carrier layer (3) comprises at least one UV absorber and at least one UV stabilizer
   and/or wherein
an UV protecting polymer layer (5), comprising at least one UV absorber and at least one UV stabilizer, is bound to the light source facing surface of carrier layer (3) either directly or via an adhesive layer (4).

Another embodiment of the present invention is a solar device, characterized in that
it is a CPV element comprising at least one solar concentration device according to the invention and at least one solar cell,
   or
it is a CSP element comprising at least one solar concentration device according to the invention and at least one heat absorber unit.

Finally the present invention relates to the use of UV protected laminated solar concentration devices to produce a solar devices, in particular a CSP or a CPV device.

Before describing the present invention in more detail, important terms are defined.

The terms “polymer layer” and “layer” hereinafter include plates, sheets, films, coating systems or coatings based on polymers. Such a layer may in principle have a thickness between 1 μm and 2 cm.

The term (meth)acrylates covers acrylates as well as methacrylates as well as combinations of both.

### DETAILED DESCRIPTION OF THE INVENTION

The inventive concentrator may have a total thickness of from 0.5 mm to 50 mm, preferably of from 1 mm to 25 mm, more preferably of from 2 to 20 mm and particular preferred of from 3 mm to 10 mm.

A preferred solar concentration device according to the invention is described below in detail while reference is made to FIG. 1.

### Polymeric Film (1)

Manufacture of polymeric films with embossed Fresnel lense structures is well known in the art, e.g. it is described in U.S. Pat. No. 5,656,209, WO 01/196000 and WO 2010/097263, all of which are herein incorporated by reference in their entirety. Appropriate films are also commercially available for example from 3M Corp.

There are no particular restrictions to the material respectively the manufacturing process of polymeric film (1) despite of the fact that it must have an embossed structure of a Fresnel lens and a sufficient transparency. Thus, polymeric films (1) comprising poly(meth)acrylate, polycarbonate, cyclic olefin polymers, polystyrene, polyvinylidenedifluoride, polyurethanes or mixtures or copolymers thereof are preferred. Particular preferred are polymeric films (1) made of polymers as described in WO 2010/097263.

The Fresnel lens structure of film (1) is preferably square or rectangular, but may also have any other desired shape. In another preferred version, film (1) is configured as a linear Fresnel lens where the pattern is continuous for the length of the film. Although no particular limitation is placed on the thickness of the film, it may preferably be in the range of from 0.01 to 10 mm, preferably 0.025 to 2 mm, more preferably 0.025 to 1 mm, particular preferred from 0.05 to 0.75 mm, very particular preferred of from 0.1 to 0.5 mm or 5 to 0.9 mm. The polymeric film (1) may also consist of roughly 4″ to 36″×4″ to 36″ square individual lenses arranged in a grid pattern (see FIG. 2).

Polymeric film (1) might comprise additives, preferably eat stabilizers, impact modifiers, UV absorbers, UV stabilizers, release agents, lubricants or additives to improve meltflow or chemical and craze resistance. Such additives are known in the art.

### Polymeric Carrier Layer (3)

Carrier layer (3) is made of highly transparent (co)polymers or of a blend of different polymers. It is preferably applied in form of a sheet. Preferred polymers comprise polyesters, preferably polyethyleneterephtalathe or PETG, polycarbonates, polystyrenes, styrene copolymers, fluoropolymers and poly(meth)acrylates. Particular preferred are PMMA or a fluoropolymer, the fluoropolymer being, for example, polyvinylidene fluoride (PVDF). In particular PMMA or PVDF-Polymers as described below for the UV protection layer (5) can be used.

Carrier layer (3) may be a monolayer or multilayer system of different polymers. One example for a multilayer system is a system composed of polymethylmethacrylate (PMMA) and polyvinylidene fluoride (PVDF) layers. In the multilayer system, the individual additives are distributed homogeneously and/or separately from one another between one or more of these layers.

Carrier layer (3) may comprise additives, preferably to improve the weathering stability as described below and/or heat stabilizers. Without being bond to a special theory, inventors are of the opinion, that UV radiation initiates acrylic chain opening. If, however, a chain opens in the UV protected carrier layer (3), heat stabilizer stop/minimize the “unzipping” of the chain. Thus, particular preferably, a UV protection layer (5) is used and/or only heat stabilizers and/or no UV stabilizers are present in the carrier layer (3). This provides a more economical and effective system. Suitable heat stabilizers are known in the art.

It is preferred, that the carrier layer (3) comprises impact modifiers, in particular butyl acrylate based impact modifiers. In addition impact modifiers as described below for the UV protection layer (5) can be used. It has been found, that such modifiers when added to carrier layer (3) may significantly reduce the resulting warpage of a thermal laminate of film (1) and layer (3). Without being bond to a specific theory, the base polymer resin of film (1) might comprise impact modifiers, which reduce its brittleness and facilitates winding onto rolls. If the base polymer of the carrier layer (3) has no impact modifier, it has a different coefficient of thermal expansion than the film. As the carrier layer (3) cools, layer (3) and film (1) shrink to different final sizes, causing the warpage. The introduction of an impact modifier to the carrier layer (3) substrate reduces the thermal expansion coefficient differential between film (1) and layer (3), and therefore reduces warpage significantly.

Irrespective of the composition, the highly transparent carrier layer (3) has preferably a total thickness in the range from 0.1 mm to 50 mm, preferably in the range from 0.5 to 25 mm, more preferably in the range from 1 to 20 mm, particular preferred in the range of from 2 to 20 mm and very particular preferred of from 2 to 10 mm and 2 to 7 mm.

The thickness of the highly transparent polymer layer is crucial in relation to the overall lens size with larger lenses requiring greater thickness (unless additional support systems are provided). This ensures adequate stiffness to avoid lens deflection under wind load, snow load or under its own weight due to polymer creep. Deflection of the lens would result changes in the distance between the lens and the solar receiver. This will negatively the system efficiency due to poor focusing of the light. Additionally, lens thickness must be sufficient so that the lens had sufficient impact strength to resist damage from hail.

### The Stabilizer Package (Light Stabilizer)

The inventive laminated solar concentration device is UV protected by a special UV protection package comprising at least one UV absorber and at least one UV stabilizer. Said package may be added to carrier layer (3) and/or an UV protecting layer (5), comprising said UV protection package, may be used to cover carrier layer (3).

A particular constituent of the UV protected solar concentration devices in accordance with the invention is the UV protection package, which contributes to a long lifetime and to the weathering stability of the concentrators. More particularly, the laminated solar concentration device produced in accordance with the invention is notable for its significantly improved UV stability compared to the prior art and the associated longer lifetime. The inventive material can thus be used in solar concentrators over a very long period of at least 15 years, preferably even at least 20 years, more preferably at least 25 years, at sites with a particularly large number of sun hours and particularly intense solar radiation, for example in the South-Western USA or the Sahara.

Light stabilizers are well known and are described in detail by way of example in Hans Zweifel, Plastics Additives Handbook, Hanser Verlag, 5th Edition, 2001, p. 141 ff. Light stabilizers are understood to include UV absorbers, UV stabilizers and free-radical scavengers.

UV absorbers can by way of example derive from the group of the substituted benzophenones, salicylic esters, cinnamic esters, oxanilides, benzoxazinones, hydroxyphenylbenzotriazoles, triazines or benzylidenemalonate.

The best-known representatives of the UV stabilizers/free-radical scavengers are provided by the group of the sterically hindered amines (hindered amine light stabilizer, HALS).

The individual additives of the UV protection package may be distributed homogeneously and/or separately from one another between one or more of the layers of the inventive solar concentration device.

Typical UV absorbers which may be used are intrapolymerizable UV absorbers containing groups with high absorption in the wavelength range from 290 to 370 nm. Preference is given to monomers whose UV absorption in the form of a layer of thickness 5 mm of a solution in chloroform (spectroscopic quality) at a concentration of 0.002% by weight is at least 10%. Examples of suitable compounds are derivatives of 2-hydroxybenzophenone, of hydroxyacetophenone, of cyano-β,β-biphenyl, of hydroxybenzoic esters, of oxanilide, of p-aminobenzoic esters or of the 6,8-dialkyl-4-oxo-5-chromanyl group. The ethylenically unsaturated groups which are present in these monomers and which are capable of free-radical polymerization are preferably acrylic, methacrylic, allyl or vinyl groups.

Examples of suitable monomers are: 2-(cyano-β,β-biphenylacryloyloxy)ethyl-1 methacrylate, 2-(2′-hydroxy-3′-methacrylamidomethyl-5′-octylphenyl)benzotriazole, 2-hydroxy-4-(2-hydroxy-3-methacryloyloxy)propoxybenzophenone, 2-(alpha-cyano-β,β-biphenylacryloyloxy)ethyl-2-methacrylamide, 2-hydroxy-4-methacryloyloxybenzophenone, 2-hydroxy-4-acryloyloxyethyloxybenzophenone, N-(4-methacryloylphenol)-N′-(2-ethylphenyl)oxamide, vinyl 4-ethyl-alpha-cyano-β-phenylcinnamate, 2-(2-hydroxy-5-vinylphenyl)-2-benzotriazole.

The selected proportion of the UV-absorbing monomers in a layer of the inventive solar concentration device can advantageously be sufficiently high that the foil layer absorbs at least 98% of the incident UV radiation whose wavelength is from 290 to 370 nm. The concentration required for this depends on the layer thickness and on the effectiveness of the monomer. It is generally from 0.1% by weight to 2% by weight, based on the weight of the monomers used for preparation of the layer.

Copolymerizable UV absorbers have the disadvantage of not migrating. During the course of weathering, the upper layer exposed to UV light and weathering becomes increasingly depleted in UV absorber, but no unused UV absorber can diffuse to replace it because the molecule has been immobilized as a constituent of the polymer, and the layer is unprotected from the attacks of UV radiation and weathering.

In contrast, the use of non-copolymerizable UV absorbers permits consequent migration of the UV absorber to the surface. At the same time, however, it is desirable to avoid bleeding of the migratory UV absorber from the plastics moulding during processing, e.g. extrusion. Preference is therefore given here to the use of involatile light stabilizers. Volatility can be determined by way of the weight loss in TGA to DIN ISO 11358. Preference is given here to light stabilizers which, when this test is carried out on the pure substance with a heating rate of 20° C./min in air, exhibit a weight loss of 2% at a temperature above 240° C., preferably above 270° C. and particularly preferably greater than 300° C.

In a preferred embodiment of the present invention, the UV protection package comprises at least two of the following components:
A) UV absorber of the benzotriazole type,
B) UV absorber of the triazine type,
C) UV stabilizer, preferably an HALS compound.

Components A) and B) can be used as an individual substance or in mixtures. At least one UV absorber component must be present in the laminate of the invention. Component C) is necessarily present in the laminate of the present invention.

### Component A: UV Absorber of Benzotriazole Type

Examples of UV absorbers of benzotriazole type that can be used are 2-(2-hydroxy-5-methylphenyl)benzotriazole, 2-[2-hydroxy-3,5-di(alpha,alpha-dimethylbenzyl)phenyl]-benzotriazole, 2-(2-hydroxy-3,5-di-tert-butylphenyl)benzo-triazole, 2-(2-hydroxy-3,5-butyl-5-methylphenyl)-5-chloro-benzotriazole, 2-(2-hydroxy-3,5-di-tert-butylphenyl)-5-chlorobenzotriazole, 2-(2-hydroxy-3,5-di-tert-amyl-phenyl)benzotriazole, 2-(2-hydroxy-5-tert-butyl-phenyl)benzotriazole, 2-(2-hydroxy-3-sec-butyl-5-tert-butylphenyl)benzotriazole and 2-(2-hydroxy-5-tert-octyl-phenyl)benzotriazole, phenol, 2,2′-methylenebis[6-(2H-benzotriazol-2-yl)-4-(1,1,3,3-tetramethylbutyl)].

The amounts used of the UV absorbers of benzotriazole type are from 0.1% by weight to 10% by weight, preferably from 0.2% by weight to 6% by weight and very particularly preferably from 0.5% by weight to 4% by weight, based on the weight of the monomers used to prepare the respective layer. It is also possible to use mixtures of different UV absorbers of benzotriazole type.

### Component B: UV Absorber of Triazine Type

Triazines, such as 2-(4,6-diphenyl-1,3,5-triazin-2-yl)-5-hexyloxyphenol, can moreover also be used as UV stabilizers in the mixture.

The amounts used of the triazines are from 0.0% by weight to 5% by weight, preferably from 0.1% by weight to 5% by weight, particular preferably 0.2% by weight to 3% by weight, very particularly preferably from 0.5% by weight to 3% by weight and especially preferably from 0.5% by weight to 2% by weight, based on the weight of the monomers used to prepare the respective layers. It is also possible to use mixtures of different triazines.

### Component C: UV Stabilizers

An example which may be mentioned here for free-radical scavengers/UV stabilizers is sterically hindered amines, known as HALS (Hindered Amine Light Stabilizer). They can be used to inhibit ageing phenomena in paints and plastics, especially in polyolefin plastics (Kunststoffe, 74 (1984) 10, pp. 620-623; Farbe+Lack, Volume 96, 9/1990, pp. 689-693). The tetramethylpiperidine group present in the HALS compounds is responsible for the stabilizing effect. This class of compound can have no substitution on the piperidine nitrogen or else substitution by alkyl or acyl groups on the piperidine nitrogen. The sterically hindered amines do not absorb in the UV region. They scavenge free radicals that have been formed, whereas the UV absorbers cannot do this. Examples of HALS compounds which have stabilizing effect and which can also be used in the form of mixtures are: bis(2,2,6,6-tetramethyl-4-piperidyl)sebacate, 8-acetyl-3-dodecyl-7,7,9,9-tetramethyl-1,3,8-triazaspiro(4,5)-decane-2,5-dione, bis(2,2,6,6-tetramethyl-4-piperidyl)succinate, poly(N-β-hydroxyethyl-2,2,6,6-tetramethyl-4-hydroxypiperidine succinate) or bis(N-methyl-2,2,6,6-tetramethyl-4-piperidyl)sebacate.

The amounts used of the HALS compounds are from 0.0% by weight to 5% by weight, preferably from 0.1% by weight to 5% by weight, particular preferably from 0.1% by weight to 3% by weight and very particularly preferably from 0.2% by weight to 2% by weight, based on the weight of the monomers used to prepare the respective layer. It is also possible to use mixtures of different HALS compounds.

Other costabilizers that can be used moreover are the HALS compounds described above, disulphites, such as sodium disulphite, and sterically hindered phenols and phosphites.

The wavelength spectrum of solar radiation relevant for “solar thermal energy uses” ranges from 300 nm to 2500 nm. The range below 400 nm, especially below 375 nm, should, however, be filtered out to prolong the lifetime of the concentrator, such that the “effective wavelength range” from 375 nm or from 400 nm to 2500 nm is preserved. The mixture of UV absorbers and UV stabilizers used in accordance with the invention exhibits stable, long-lived UV protection over a broad wavelength spectrum (300 nm-400 nm).

It is particular preferred, that the inventive laminates comprise the UV protecting package in form of an UV protecting layer (5). Inventors have found, that this construction is particular advantageous in view of avoiding respectively minimizing the reduction of the molecular mass of the polymer layers during use of the inventive solar concentration devices respectively the quary out of impact modifiers from polymeric layers.

Another advantage of this alternative compared to the alternative wherein the UV protection package is added to carrier layer (3) is, that the amount of UV absorbers and stabilizers needed to achieve the same effect is lower because layer (5) usually is thinner than layer (3).

Appropriate UV protection for films which might be used as UV protecting layer (5) can be found, for example, in WO 2007/073952 (Evonik Röhm) or in DE 10 2007 029 263 A1 or in WO 2007/074138 respectively will be described in more detail below. All of said documents are incorporated by reference in their entirety.

### UV Protecting Layer (5)

Preferred UV protecting layers (5) consist of a transparent single- or multilayer (multi-sublayer) plastics foil, encompassing polymethyl (meth)acrylate (PMMA) or polymethyl (meth)acrylate (PMMA) and polyvinylidene fluoride (PVDF), in each case in at least one sublayer, or PMMA and PVDF in a mixture in at least one sublayer.

The UV protecting layer (5) may preferably have a thickness in the range from 10 to 250 μm, more preferably in the range from 40 to 120 μm and particular preferred of from 50 to 90 μm.

Particularly preferred components of said layer (5) beside of the UV stabilizing package are PMMA based plastics and PVDF polymers as described below:

Polymethyl methacrylate plastics are generally obtained by free-radical polymerization of mixtures which comprise methyl methacrylate. These mixtures generally comprise at least 40% by weight, preferably at least 60% by weight and particularly preferably at least 80% by weight, based on the weight of the monomers, of methyl methacrylate.

These mixtures for production of polymethyl methacrylates can also comprise other (meth)acrylates copolymerizable with methyl methacrylate. The expression (meth)acrylates comprises methacrylates and acrylates and mixtures of the two. These monomers are well known. Among them are, inter alia, (meth)acrylates which derive from saturated alcohols, e.g. methyl acrylate, ethyl (meth)acrylate, propyl (meth)acrylate, n-butyl (meth)acrylate, tert-butyl (meth)acrylate, isobutyl (meth)acrylate, pentyl (meth)acrylate and 2-ethylhexyl (meth)acrylate; and also (meth)acrylates which derive from unsaturated alcohols, e.g. oleyl (meth)acrylate, 2-propynyl (meth)acrylate, allyl (meth)acrylate, vinyl (meth)acrylate; and also aryl (meth)acrylates, such as benzyl (meth)acrylate or phenyl (meth)acrylate, and in each case the aryl radicals here can be unsubstituted or can have up to four substituents; cycloalkyl (meth)acrylates, such as 3-vinylcyclohexyl (meth)acrylate, bornyl (meth)acrylate; hydroxyalkyl (meth)acrylates, such as 3-hydroxypropyl (meth)acrylate, 3,4-dihydroxybutyl (meth)acrylate, 2-hydroxyethyl (meth)acrylate, 2-hydroxypropyl (meth)acrylate; glycol di(meth)acrylates, such as 1,4-butanediol (meth)acrylate, (meth)acrylates of ether alcohols, e.g. tetrahydrofurfuryl (meth)acrylate, vinyloxyethoxyethyl (meth)acrylate; amides and nitriles of (meth)acrylic acid, e.g. N-(3-dimethylaminopropyl) (meth)acrylamide, N-(diethylphosphono) (meth)acrylamide, 1-methacryloylamido-2-methyl-2-propanol; sulphur-containing methacrylates, such as ethylsulphinylethyl (meth)acrylate, 4-thiocyanatobutyl (meth)acrylate, ethylsulphonylethyl (meth)acrylate, thiocyanatomethyl (meth)acrylate, methylsulphinylmethyl (meth)acrylate, bis((meth)acryloyloxyethyl) sulphide; polyfunctional (meth)acrylates, such as trimethyloylpropane tri(meth)acrylate.

The polymerization reaction is generally initiated by known free-radical initiators. Among the preferred initiators are, inter alia, the azo initiators well known to persons skilled in the art, e.g. AIBN and 1,1-azobiscyclohexanecarbonitrile, and peroxy compounds, such as methyl ethyl ketone peroxide, acetylacetone peroxide, dilauryl peroxide, tert-butyl 2-ethylperhexanoate, ketone peroxide, methyl isobutyl ketone peroxide, cyclohexanone peroxide, dibenzoyl peroxide, tert-butyl peroxybenzoate, tert-butylperoxy isopropyl carbonate, 2,5-bis(2-ethylhexanoylperoxy)-2,5-dimethylhexane, tert-butyl 2-ethylperoxyhexanoate, tert-butyl 3,5,5-trimethylperoxyhexanoate, dicumyl peroxide, 1,1-bis(tert-butylperoxy)cyclohexane, 1,1-bis(tert-butylperoxy)-3,3,5-trimethylcyclohexane, cumyl hydroperoxide, tert-butyl hydroperoxide, bis(4-tert-butylcyclohexyl)peroxydicarbonate, mixtures of two or more of the abovementioned compounds with one another and mixtures of the abovementioned compounds with compounds that have not been mentioned but which can likewise form free radicals.

The compositions to be polymerized can comprise not only the (meth)acrylates described above but also other unsaturated monomers which are copolymerizable with methyl methacrylate and with the abovementioned (meth)acrylates. Among these are, inter alia, 1-alkenes, such as 1-hexene, 1-heptene; branched alkenes, such as vinylcyclohexane, 3,3-dimethyl-1-propene, 3-methyl-1-diisobutylene, 4-methyl-1-pentene; acrylonitrile; vinyl esters, such as vinyl acetate; styrene, substituted styrenes having an alkyl substituent in the side chain, e.g. α-methylstyrene and α-ethylstyrene, substituted styrenes having an alkyl substituent on the ring, e.g. vinyltoluene and p-methylstyrene, halogenated styrenes, such as monochlorostyrenes, dichlorostyrenes, tribromostyrenes and tetrabromostyrenes; heterocyclic vinyl compounds, such as 2-vinylpyridine, 3-vinylpyridine, 2-methyl-5-vinylpyridine, 3-ethyl-4-vinylpyridine, 2,3-dimethyl-5-vinylpyridine, vinylpyrimidine, vinylpiperidine, 9-vinylcarbazole, 3-vinylcarbazole, 4-vinylcarbazole, 1-vinylimidazole, 2-methyl-1-vinylimidazole, N-vinylpyrrolidone, 2-vinylpyrrolidone, N-vinylpyrrolidine, 3-vinylpyrrolidine, N-vinylcaprolactam, N-vinylbutyrolactam, vinyloxolane, vinylfuran, vinylthiophene, vinylthiolane, vinylthiazoles and hydrogenated vinylthiazoles, vinyloxazoles and hydrogenated vinyloxazoles; vinyl ethers and isoprenyl ethers; maleic acid derivatives, such as maleic anhydride, methylmaleic anhydride, maleimide, methylmaleimide; and dienes, such as divinylbenzene.

The amount generally used of these comonomers is from 0% by weight to 60% by weight, preferably from 0% by weight to 40% by weight and particularly preferably from 0% by weight to 20% by weight, based on the weight of monomers, and the compounds here can be used individually or in the form of a mixture.

Further preference is given to a foil using a poly(meth)acrylate which is obtainable by polymerization of a composition having, as polymerizable constituents:
a. from >50% by weight to 99.9% by weight of methyl methacrylate,
b. from 0.1% by weight to <50% by weight of an acrylate having an ester radical deriving from a C1-C4 alcohol,
c. from 0% by weight to 10% by weight of monomers copolymerizable with the monomers a. and b.

Further preference is given to a foil using a poly(meth)acrylate which is obtainable by polymerization of a composition having, as polymerizable constituents:
a. from 78% by weight to 92% by weight of methyl methacrylate,
b. from 8% by weight to 12% by weight of an acrylate having an ester radical deriving from a C1-C4 alcohol,
c. from 0% by weight to 10% by weight of monomers copolymerizable with the monomers a. and b.

Surprisingly, it has been found that use of a coacrylate proportion in the range from 8 to 12 percent by weight, preferably using that amount of an n-butyl acrylate, raises the intrinsic stability of the foil markedly beyond the extent hitherto known. This had not therefore been readily foreseeable. As the coacrylate proportion selected increases, the stability of the foil increases. Furthermore, an increase beyond the limiting values is in turn disadvantageous, since the additional proportions of coacrylate do not bring about any significant addition of suppression of cracking.

The chain lengths of the polymers can be adjusted by polymerization of the monomer mixture in the presence of molecular-weight regulators, particular examples being the mercaptans known for this purpose, e.g. n-butyl mercaptan, n-dodecyl mercaptan, 2-mercaptoethanol or 2-ethylhexyl thioglycolate, or pentaerythritol tetrathioglycolate; the amounts generally used of the molecular-weight regulators being from 0.05 to 5% by weight, based on the monomer mixture, preference being given to amounts of from 0.1 to 2% by weight and particular preference being given to amounts of from 0.2 to 1% by weight, based on the monomer mixture (cf. by way of example H. Rauch-Puntigam, Th. Völker, “Acryl- and Methacrylverbindungen” [“Acrylic and Methacrylic Compounds”], Springer, Heidelberg, 1967; Houben-Weyl, Methoden der organischen Chemie, [Methods of Organic Chemistry], Vol. XIV/1, page 66, Georg Thieme, Heidelberg, 1961, or Kirk-Othmer, Encyclopedia of Chemical Technology, Vol. 1, pages 296 et seq., J. Wiley, New York, 1978).

The poly(meth)acrylate has preferably been rendered impact-resistant by using an impact modifier.

In one preferred variant, the amount of impact modifier is from 1% to 50% by weight, based on the entirety of poly(meth)acrylate and impact modifier in foil (5).

In another preferred variant, the impact-modified poly(meth)acrylate plastic in foil (5) is composed of from 20% by weight to 80% by weight, preferably from 30% by weight to 70% by weight, of a poly(meth)acrylate matrix and of from 80% to 20% by weight, preferably from 70% by weight to 30% by weight, of elastomer particles whose average particle diameter is from 10 to 150 nm (measurements by way of example using the ultracentrifuge method).

The poly(meth)acrylate and the impact modifier are preferably derived from a core-shell polymer, where the shell forms a matrix composed of polymer in the subsequent foil (5).

The elastomer particles dispersed in the poly(meth)acrylate matrix preferably have a core using a soft elastomer phase and using a hard phase bonded thereto.

The impact-modified poly(meth)acrylate plastic (imPMMA) is composed of a proportion of matrix polymer, polymerized from at least 80% by weight of units of methyl methacrylate, and also, if appropriate, from 0% by weight to 20% by weight of units of monomers copolymerizable with methyl methacrylate, and of a proportion of impact modifiers based on crosslinked poly(meth)acrylates and dispersed in the matrix.

The matrix polymer is composed in particular of from 80% by weight to 100% by weight, preferably from 90% by weight to 99.5% by weight, of methyl methacrylate units capable of free-radical polymerization and, if appropriate, from 0% by weight to 20% by weight, preferably from 0.5% by weight to 12% by weight, of further comonomers capable of free-radical polymerization, e.g. C₁-C₄-alkyl(meth)acrylates, in particular methyl acrylate, ethyl acrylate or butyl acrylate. As the molecular weight of the matrix polymers increases, the weathering resistance of the UV-protection foil improves.

In one particular embodiment of the invention, the foil is characterized by a weight-average molar mass M_{w} of the poly(meth)acrylate of ≧80 000 g/mol, determined by means of gel permeation chromatography (GPC). The weight-average molar mass M_{w} of the poly(meth)acrylate is more preferably ≧120 000 g/mol, determined likewise by means of gel permeation chromatography (GPC). For the purposes of the invention, it is possible to achieve foils of even greater weathering resistance if the weight-average molar mass M_{w} of the poly(meth)acrylate is ≧140 000 g/mol, determined by means of gel permeation chromatography (GPC). The average (weight-average) molar mass M_{w} of the matrix is generally in the range from 80 000 g/mol to 200 000 g/mol (M_{w} being determined by means of gel permeation chromatography with reference to polymethyl methacrylate as calibration standard, as for all of the M_{w} determinations on the matrix PMMA). However, particularly good weathering resistances are obtained from foils whose matrix polymer has an average molar mass M_{w} (weight-average) in the range from 80 000 g/mol to 180 000 g/mol, preferably in the range from 108 000 g/mol to 180 000 g/mol, more preferably in the range from 122 000 g/mol to 180 000 g/mol, in each case determined by means of GPC against PMMA calibration standards. An example of another method for determination of the molar mass M_{w}, alongside the GPC method, is a light-scattering method (see, for example, H. F. Mark et al., Encyclopedia of Polymer Science and Engineering, 2nd Edition, Vol. 10, pages 1 et seq., J. Wiley, 1989).

Preference is given to a copolymer composed of from 85% by weight to 99.5% by weight of methyl methacrylate and from 0.5% by weight to 15% by weight of methyl acrylate, which, if appropriate, has an optional proportion of from 0-12% by weight of butyl acrylate, the amounts here being based on 100% by weight of the polymerizable constituents. Particularly advantageous copolymers are those obtainable by copolymerization of from 90% by weight to 99.5% by weight of methyl methacrylate and from 0.5% by weight to 10% by weight of methyl acrylate, which, if appropriate, has an optional proportion of from 0% by weight to 10% by weight of butyl acrylate, where the amounts are based on 100% by weight of the polymerizable constituents. More preference is given to copolymers which are obtainable from 92.5% by weight to 97.5% by weight of methyl methacrylate and from 2.5% by weight to 7.5% by weight of methyl acrylate which, if appropriate, has an optional proportion of from 0% by weight to 7% by weight of butyl acrylate, where the amounts are based on 100% by weight of the polymerizable constituents. The Vicat softening points VSP (ISO 306-B50) can be in the region of at least 90° C., preferably from 95° C. to 112° C.

The impact modifier and matrix polymer can be mixed in the extruder in the melt to give impact-modified polymethacrylate moulding compositions. The material discharged is generally first chopped to give pellets. These can be further processed by means of extrusion or injection moulding to give mouldings, such as sheet, foils or injection-moulded parts.

The polymethacrylate matrix in foil (5) comprises an impact modifier which by way of example can be a core-shell polymer having a two- or three-shell structure, preference being given to use of two-shell impact modifiers.

Impact modifiers for polymethacrylate plastics are well known. EP-A 0 113 924, EP-A 0 522 351, EP-A 0 465 049 and EP-A 0 683 028 describe by way of example the preparation and structure of impact-modified polymethacrylate moulding compositions.

From 1% by weight to 35% by weight, preferably from 2% by weight to 20% by weight, particularly preferably from 3% by weight to 15% by weight, in particular from 5% by weight to 12% by weight, of an impact modifier which is an elastomer phase composed of crosslinked polymer particles is present in the polymethacrylate matrix. The impact modifier is obtained in a manner known per se by bead polymerization or by emulsion polymerization.

In the simplest case materials involved are crosslinked particles obtained by means of bead polymerization whose average particle size is in the range from 10 nm to 150 nm, preferably from 20 nm to 100 nm, in particular from 30 nm to 90 nm. These are generally composed of at least 40% by weight, preferably from 50% by weight to 70% by weight, of methyl methacrylate, from 20% by weight to 40% by weight, preferably from 25% by weight to 35% by weight, of butyl acrylate, and from 0.1% by weight to 2% by weight, preferably from 0.5% by weight to 1% by weight, of a crosslinking monomer, e.g. a polyfunctional (meth)acrylate, e.g. allyl methacrylate and, if appropriate, other monomers, e.g. from 0% by weight to 10% by weight, preferably from 0.5% by weight to 5% by weight, of C₁-C₄-alkyl methacrylates, such as ethyl acrylate or butyl methacrylate, preferably methyl acrylate, or other vinylically polymerizable monomers, e.g. styrene.

Preferred impact modifiers are polymer particles which can have a two- or three-layer core-shell structure and are obtained by emulsion polymerization (see, for example, EP-A 0 113 924, EP-A 0 522 351, EP-A 0 465 049 and EP-A 0 683 028). However, the invention requires suitable particle sizes of these emulsion polymers in the range from 10 nm to 150 nm, preferably from 20 nm to 120 nm, particularly preferably from 50 nm to 100 nm.

A three-layer or three-phase structure with a core and two shells can be created as follows. The innermost (hard) shell can, for example, be composed in essence of methyl methacrylate, of small proportions of comonomers, e.g. ethyl acrylate, and of a proportion of crosslinking agent, e.g. allyl methacrylate. The middle (soft) shell can, for example, be composed of butyl acrylate and, if appropriate, styrene, while the outermost (hard) shell is in essence the same as the matrix polymer, thus bringing about compatibility and good linkage to the matrix. The proportion of polybutyl acrylate in the impact modifier is decisive for the impact-modifying action and is preferably in the range from 20% by weight to 40% by weight, particularly preferably in the range from 25% by weight to 35% by weight.

Preference is given, in particular for foil production, but not restricted thereto, to use of a system known in principle from EP 0 528 196 A1 which is a two-phase impact-modified polymer composed of:
a1) from 10% by weight to 95% by weight of a coherent hard phase whose glass transition temperature T_{mg} is above 70° C., composed of
   a11) from 80% by weight to 100% by weight (based on a1) of methyl methacrylate and
   a12) from 0% by weight to 20% by weight of one or more other ethylenically unsaturated monomers capable of free-radical polymerization, and
a2) from 90% by weight to 5% by weight of a tough phase whose glass transition temperature T_{mg} is below −10° C., distributed in the hard phase and composed of
   a21) from 50% by weight to 99.5% by weight of a C₁-C₁₀-alkyl acrylate (based on a2)
   a22) from 0.5% by weight to 5% by weight of a crosslinking monomer having two or more ethylenically unsaturated radicals which are capable of free-radical polymerization, and
   a23) if appropriate other ethylenically unsaturated monomers capable of free-radical polymerization,
      where at least 15% by weight of the hard phase a1) has covalent linkage to the tough phase a2).

The two-phase impact modifier can be produced by a two-stage emulsion polymerization reaction in water, as described by way of example in DE-A 38 42 796. In the first stage, the tough phase a2) is produced and is composed of at least 50% by weight, preferably more than 80% by weight, of lower alkyl acrylates, thus giving a glass transition temperature T_{mg} below −10° C. for this phase. Crosslinking monomers a22) used comprise (meth)acrylates of diols, e.g. ethylene glycol dimethacrylate or 1,4-butanediol dimethacrylate, aromatic compounds having two vinyl or allyl groups, e.g. divinylbenzene, or other crosslinking agents having two ethylenically unsaturated radicals which are capable of free-radical polymerization, e.g. allyl methacrylate, as graft-linking agent. Crosslinking agents that may be mentioned by way of example and have three or more unsaturated groups which are capable of free-radical polymerization, e.g. allyl groups or (meth)acrylic groups, are triallyl cyanurate, trimethylolpropane triacrylate and trimethylolpropane trimethacrylate, and pentaerythrityl tetraacrylate and pentaerythrityl tetramethacrylate. U.S. Pat. No. 4,513,118 gives other examples in this connection.

The ethylenically unsaturated monomers capable of free-radical polymerization and mentioned under a23) can, by way of example, be acrylic or methacrylic acid or else their alkyl esters having from 1 to 20 carbon atoms but not mentioned above, and the alkyl radical here can be linear, branched or cyclic. Furthermore, a23) can comprise further aliphatic comonomers which are capable of free-radical polymerization and which are copolymerizable with the alkyl acrylates a21). However, the intention is to exclude significant proportions of aromatic comonomers, such as styrene, alpha-methylstyrene or vinyltoluene, since they lead to undesired properties of the moulding composition—especially on weathering.

When the tough phase is produced in the first stage, careful attention has to be paid to the setting of the particle size and its polydispersity. The particle size of the tough phase here is in essence dependent on the concentration of the emulsifier. The particle size can advantageously be controlled by the use of a seed latex. Particles whose average (weight-average) particle size is below 130 nm, preferably below 70 nm, and whose particle-size polydispersity P₈₀ is below 0.5 (P₈₀ being determined from cumulative evaluation of the particle-size distribution determined by ultracentrifuge; the relationship is: P₈₀=[(r₉₀−r₁₀]/r₅₀]−1, where r₁₀, r₅₀, r₉₀=average cumulative particle radius, being the value which is greater than 10, 50, 90% of the particle radii and is smaller than 90, 50, 10% of the particle radii), preferably below 0.2, are achieved using emulsifier concentrations of from 0.15 to 1.0% by weight, based on the aqueous phase. This applies especially to anionic emulsifiers, examples being the particularly preferred alkoxylated and sulphated paraffins. Examples of polymerization initiators used are from 0.01% by weight to 0.5% by weight of alkali metal peroxodisulphate or ammonium peroxodisulphate, based on the aqueous phase, and the polymerization reaction is initiated at temperatures of from 20 to 100° C. Preference is given to use of redox systems, an example being a combination composed of from 0.01% by weight to 0.05% by weight of organic hydroperoxide and from 0.05 to 0.15% by weight of sodium hydroxymethylsulphinate, at temperatures of from 20 to 80° C.

The glass transition temperature of the hard phase a1) of which at least 15% by weight has covalent bonding to the tough phase a2) is at least 70° C. and this phase can be composed exclusively of methyl methacrylate. Up to 20% by weight of one or more other ethylenically unsaturated monomers which are capable of free-radical polymerization can be present as comonomers a12) in the hard phase, and the amount of alkyl (meth)acrylates used here, preferably alkyl acrylates having from 1 to 4 carbon atoms, is such that the glass transition temperature is not below the glass transition temperature mentioned above.

The polymerization of the hard phase a1) proceeds likewise in emulsion in a second stage, using the conventional auxiliaries, for example those also used for polymerization of the tough phase a2).

The UV-protecting foil (5) may also comprise PVDF polymers. PVDF polymers used for the purposes of the invention are polyvinylidene fluorides, these generally being transparent, semicrystalline, thermoplastic fluoroplastics. The fundamental unit for polyvinylidene fluoride is vinylidene fluoride, which is reacted (polymerized) by means of a specific catalyst to give polyvinylidene fluoride in high-purity water under controlled conditions of pressure and of temperature. Vinylidene fluoride is in turn obtainable by way of example from hydrogen fluoride and methylchloroform as starting materials, by way of chlorodifluoroethane as precursor. For the purposes of the invention it is possible in principle to obtain good success by using any commercial grade of PVDF. Among these are Kynar® grades produced by Arkema, Dyneon® grades produced by Dyneon, and also Solef® grades produced by Solvay.

An extremely high-performance weathering-protection foil (5) can be obtained by using the combination of PMMA/PVDF in an inventive foil in the inventive range of amounts of poly(meth)acrylate and polyvinylidene fluoride in a ratio of from 1:0.01 to 1:1 (w/w), in conjunction with the inventive UV stabilizer and UV absorber package.

In one preferred variant, the inventive layer (5) is a single-layer foil. This low-cost variant features a blend of PMMA and PVDF in a single layer.

These embodiments are of very particular interest as single-layer weathering-protection foil (5). Further preference is given to modifications in which the foil (5) encompasses a mixture of poly(meth)acrylate and polyvinylidene fluoride in a ratio of from 1:0.15 to 1:0.40 (w/w), the ratio preferably being from 1:0.15 to 1:0.30 (w/w).

In another preferred variant, the inventive foil (5) is a multilayer foil. This means that it has more than one sublayer, and the at least two sublayers differ from one another in the composition of the individual sublayer. One layer can therefore comprise PMMA, and another layer can comprise PVDF. The invention also includes all of the conceivable combinations, and for example one layer can comprise a blend composed of PMMA/PVDF while a second layer of the composite can comprise only PMMA or only PVDF. Further appropriate adjustment of properties can also be achieved by adding further layers composed of various materials.

Embodiments which feature at least two sublayers encompassed by the foil, at least one of which is composed of poly(meth)acrylate and at least one other of which is composed of polyvinylidene fluoride, are of very particular interest for a multilayer weathering-protection foil. Further preference is given to foils in which the foil is composed of two sublayers, of which one is a poly(methyl) methacrylate layer and the other is a polyvinylidene fluoride layer.

The foil composites mentioned composed of more than one sublayer are obtainable by foil-production processes known per se. In one preferred embodiment, the composites are obtainable by coextrusion. However, lamination processes are also conceivable, for example with or without the use of adhesion promoters.

Other foil composites preferred are those in which both layers comprise a blend, in order to raise the adhesion to one another. By way of example, an exterior PMMA layer can comprise a subordinate proportion of PVDF in order to ensure good adhesion to a layer of pure PVDF.

The UV protecting layer (5) in the form of monofilm or film having more than one sublayer can be produced with any desired thickness. A decisive factor here is always the high transparency of the outer film, coupled with exceptional weathering resistance, and also with the extremely high level of weathering protection provided to the substrate.

The single- or multilayer outer film is produced via methods known per se, an example being extrusion through a flat-film die, blown-film extrusion, or solution casting.

### Surface Protection Layer (7)

The surface protecting layer (7) may preferably be applied as surface coating layer (7). The term “surface coating” in the context of this invention is understood as a collective term for coatings which are applied to reduce surface scratching and/or to improve abrasion resistance and/or as an antisoil coating and/or as coating with anti-reflection properties. Anti-reflection properties, thereby increasing total light transmission.

To improve the scratch resistance or the abrasion resistance, polysiloxanes, such as CRYSTALCOAT™ MP-100 from SDC Technologies Inc., AS 400-SHP 401 or UVHC3000K, both from Momentive Performance Materials, can be used. These coating formulations are applied, for example, by means of roll-coating, knife-coating or flow-coating to the surface of the highly transparent polymer layer of the concentrator.

More precise details of antisoil coatings can be found in the literature or are known to those skilled in the art.

### Adhesive Layers

Optionally, adhesive layers may be present between each of the individual layers of the inventive laminate. More precisely, adhesive layers may be present
between the polymeric film (1) and carrier layer (3)=>adhesive layer (2)
   and/or
between carrier layer (3) and UV-protecting layer (5)=>adhesive layer (4)
   and/or
between UV-protecting layer (5) and surface protecting layer (7)=>adhesive layer (6)
   and/or
between the individual layers of a multilayer layers (3) and/or (5).

The adhesive systems used for this purpose are determined, in terms of their composition, from the adhesion properties of the two layers to be adhesive-bonded to one another. In addition, the adhesive systems should contribute to long-life performance, and prevent adverse interactions of the adjacent layers.

Under some circumstances, the optical properties are also of great significance. Adhesive layers must be highly transparent. Suitable examples are especially acrylate adhesives.

Particular preference is given to inventive laminates, wherein no adhesive layer (2) is present, i.e. wherein polymeric film (1) and carrier layer (3) are thermally laminated. Production of such laminates is described in WO 2009/121708, which is incorporated by reference in its entirety. Said process comprises the steps of providing a film (1) having a first surface embossed with optical structures which form one ore more Fresnel lens(es) and an opposite second surface; guiding the film (1) to a nip point of a pair of lamination rolls; feeding a carrier layer (3) or an UV protected carrier layer or a laminate of carrier layer (3) and UV protection layer (5) or a coextrudate of carrier layer (3) and UV protection layer (5), to the nip point, the surface temperature of the surface of layer (3) which is intended to be bond to layer (1) is effective to enable thermal bonding between the polymer sheet and the film; and laminating the polymer sheet to the second surface of the film.

Said process requires no adhesives or additional heat. There are minimal sources for additional contamination other than the film itself. The additional equipment required is relatively simple and inexpensive to fabricate.

Details of said process will now be described while reference is made to FIGS. 3 and 4.

Referring to the drawings, and initially to FIG. 3, a schematic diagram is shown illustrating the process and the apparatus involved in laminating an embossed film (1) onto a polymer sheet (3). As shown in the diagram with arrow heading 100 showing direction of work flow, a polymer sheet (3) and a film (1) are fed into a nip point (12) of two calendar rolls (10) and (11) and are bonded to each other. Both of the calendar rolls are cold hard metal rolls.

As shown in FIG. 4, film (1) has a first surface (16) that is embossed with Fresnel structures and a second surface (15) that is to be laminated to polymer sheet (3). Film (1) may be embossed with any known process and is at ambient temperature before lamination. Film (1) may also be obtained from commercial sources. Referring back to FIG. 3, in one embodiment, film (1) is supplied in roll (8) and is fed into nip point (12) through one or more guiding rolls (9). It is appreciated that film (1) can be fed into nip point (12) from different angles as shown in FIG. 3. such as by offsetting Guiding Roll (9′).

In one embodiment of the invention, polymer sheet (3) is prepared from a conventional sheet extrusion process. And when the sheet is still hot and pliable, it is fed into nip point (12) to come into close contact with surface (15) (FIG. 4) of film (1). The temperature of polymer sheet (3) at nip point (12) is crucial to the success of the lamination. If the surface temperature is too low, there will be no bonding. If the surface temperature is too high, the optical structures of film (1) will be destroyed. It is appreciated that polymer sheet (3) has a surface temperature that is effective to ensure a thermal bonding between sheet (3) and film (1) while at the same time keep the integrity of the optical structures of film (1). For a 3 mm PMMA polymer sheet (3), an exemplary surface temperature at the point of operation is in the range of from about 120° C. to about 175° C. and preferably 140° C. to 160° C.

After film (1) is brought in close contact with polymer sheet (3) at nip point (12), a thermal bonding occurs and film (1) is laminated to sheet (3). There is no external heat needed during the lamination. The heat required for thermal bonding is provided by the internal heat from sheet (3). During the lamination process, the surface temperature of film (1) is maintained below its glass transition temperature to prevent the distortion of the optical structures.

After lamination, the laminate is then guided to cooling zone (14), which includes a plurality of cooling rolls. After the laminate is cooled to room temperature, nominally, 22° C., the finished product is cut, such as by a flying saw at the end point.

In another preferred option, the laminate of the present invention comprises an adhesive layer (2), preferred adhesives are solvent cements. In particular formulations high in chlorinated solvents may have processing advantages due to low flammability and rapid diffusion into the acrylic layers. Further, adhesives based on acrylates as known in the state of the art are preferred. Particular preferred as adhesive are methylenehloride or cements commercially available under the trade name ACRIFIX® from Evonik Röhm GmbH or products, Weld-On® from IPS and comparable products of other manufactures.

Other adhesives which may be used for one of the coating layers (2), (4) or (6) may be chosen depending on the substrates to be bonded to one another and by the exacting requirements imposed on the transparency of the adhesive layer. For the combination of PMMA and PET, melt adhesives are preferred. Examples of such melt adhesives are ethylene-vinyl acetate hotmelts (EVA hotmelts) or acrylate ethylene hotmelts. Acrylate-ethylene hotmelts are preferred.

PET films, or polyester or polyolefin films, may be joined to one another by means of a 2K-PU adhesive, by a melt adhesive, based on EVA or acrylate-ethylene, for example.

Other suitable adhesives are known in the art.

The adhesive layers may have a thickness of between 1 and 100 μm and preferably between 2 and 80 μm.

Methods for preparation of the inventive laminates are well known to a man skilled in the art. Examples of methods for producing the composite are lamination and/or (co)extrusion coating. Preferred options are:
I) Coextrusion of UV-protecting layer (5) and carrier layer (3), followed by lamination of polymeric film (1) to the back side carrier layer (3), either thermally as described above or by using an adhesive layer (2)
II) Extrusion lamination of carrier layer (3) and UV protecting layer (5), optionally by using an adhesive layer (4), followed by lamination of polymeric film (1) to the back side carrier layer (3), either thermally as described above or by using an adhesive layer (2)
III) Lamination of polymeric film (1) to carrier layer (3), either with or without formation of an adhesive layer (2), followed by lamination of UV protecting foil (5) to the light source facing side of carrier layer (3), either with or without formation of an adhesive layer (4),
IV) Lamination of carrier layer (3), comprising at least one UV absorber and at least one UV stabilizer, and polymeric film (1), either with or without formation of an adhesive layer (2), preferably without subsequent lamination with layers (4) and (5)

Surface coatings, i.e. layers (7) and optional (6) may be applied by known techniques.

The UV protected laminated solar concentration devices produced in accordance with the invention are preferably used as trough concentrators, which focus the light beams to a solar cell or an heat absorber unit. Consequently the present invention covers a CPV element comprising at least one solar concentration device according to the invention and at least one solar cell as well as a CSP element comprising at least one solar concentration devices according to the invention and at least one heat absorber unit.

The use of an UV protected laminated solar concentration devices according to the invention to produce a solar device, in particular a CSP or a CPV device is also subject of the present invention.

### BRIEF DESCRIPTION OF THE DRAWINGS

FIG. 1 shows the different layers of the inventive laminated solar concentration device

FIG. 2 is a front view of a laminated Fresnel film according to one embodiment of the present invention.

FIG. 3 is a schematic diagram showing the process and the apparatus involved in the lamination of an embossed film with a polymer sheet.

FIG. 4 is a schematic enlarged sectional view of a part of the apparatus of FIG. 1.

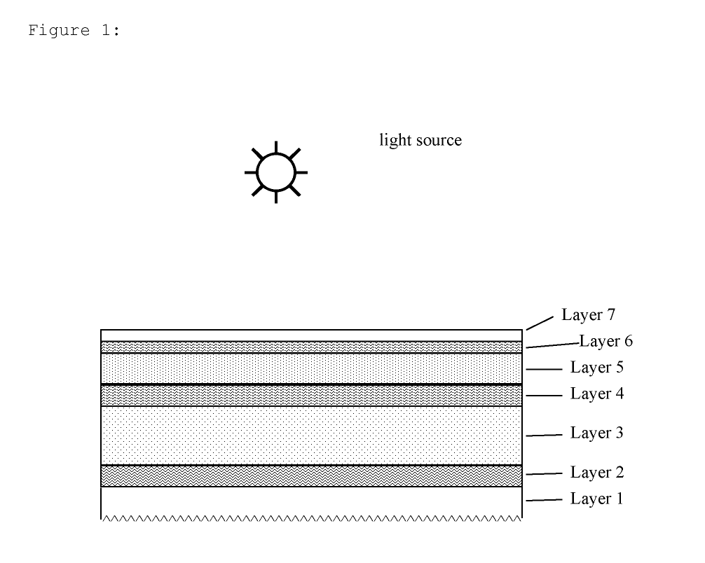

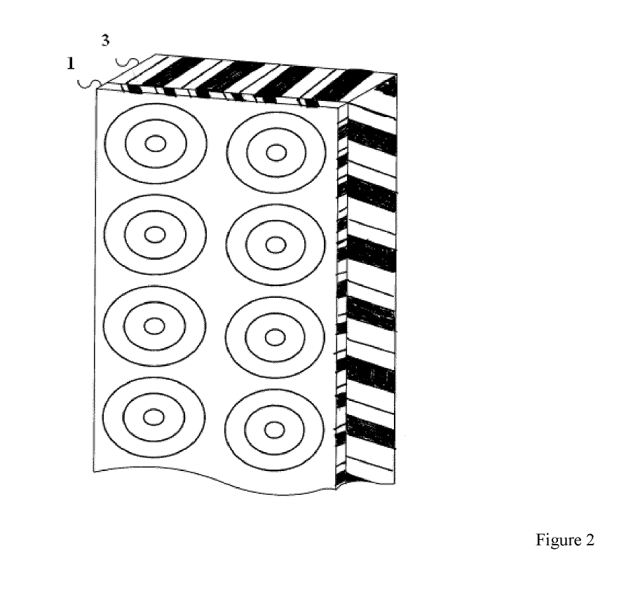

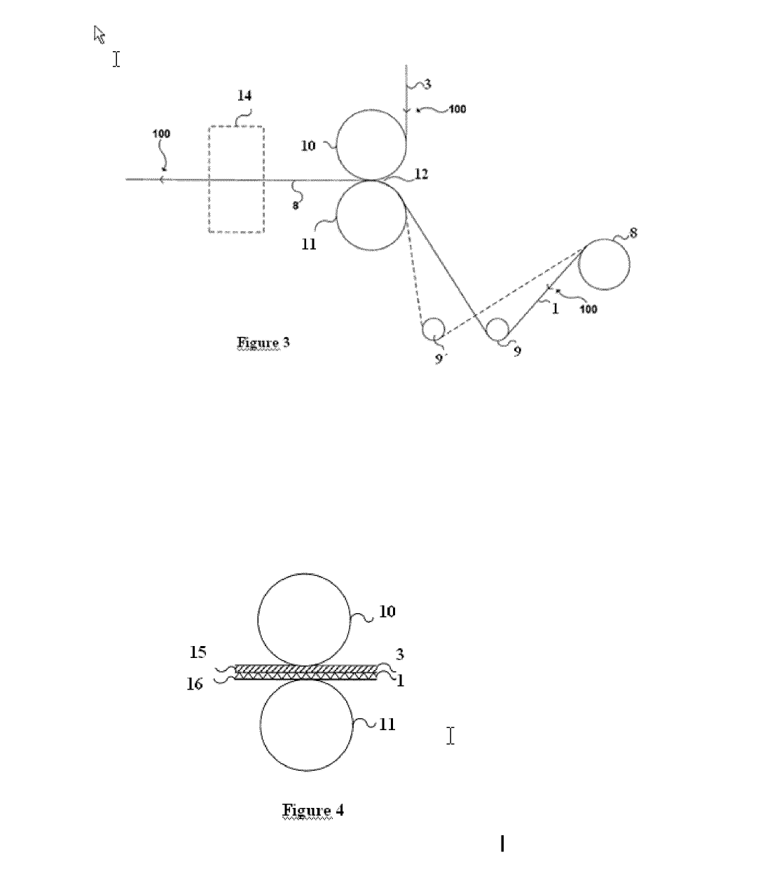

### EXAMPLES

### Example 1

A modified acrylic film (1) with an embossed pattern of multiple, circular Fresnel lenses was laminated without adhesive layer (2) to a semi-molten acrylic polymer sheet (3). The film (1) was a product of the 3M Company of Minneapolis Minn. The embossed film was supplied on a roll and was fed from the roll into a nip point of a pair of calendar rolls. The polymer sheet (3) was formed using conventional sheet extrusion process. The acrylic sheet (3) to which the film (1) was being laminated was 3 mm thick and had a surface temperature of 148° C. to 150° C. at the point of lamination. The gap between the pair of calendar rolls was adjusted to provide enough pressure to assure that the applied film had complete contact with the acrylic polymer at the point of operation. It is important to keep the temperature of the embossed surface below its glass transition temperature to maintain the sharpness of the embossed pattern. The ratio of the speed of the last roll and the haul-off rolls was maintained to a ratio of 0.980 to 1.00 to keep the embossed Fresnel lenses from becoming distorted as the sheet (3) and film (1) laminate cool to room temperature.

### Example 2

The process was the same as disclosed in Example 1, except that a continuous linear Fresnel pattern was embossed into the film (1) being applied to the sheet being formed.

### Example 3

A PMMA foil (5) of thickness 56 μm is used, composed of
a) 87.85% by weight of a polymer composed of a two-phase impact modifier according to EP 0 528 196 whose overall composition is

| | |
|---|---|
| 61.35 | % by weight of MMA |
| 37.1 | % by weight of butyl acrylate |
| 0.36 | % by weight of ethyl acrylate |
| 0.66 | % by weight of allyl methacrylate |
| 0.53 | % by weight of dodecylmercaptan, |
| | based on the above monomers, |

b) 10% by weight of PLEXIGLAS® 7H, obtainable from Röhm GmbH,
c) 1.0% by weight of Tinuvin 360 (UV absorber based on benzotriazole from Ciba SC)
   0.75% by weight of CGX UVA 006 UV-Absorber based on Triazin from Ciba SC)
   0.4% by weight of Chimassorb 119
      and this mixture is extruded by means of conventional processes to give an UV-protection foil (5).

The foil (5) is then laminated to the products of Examples 1 and 2 and the obtained products tested. The products showed improved weathering behaviour compared to conventional Fresnel lenses.

1. A UV protected laminated solar concentration device, comprising, as
viewed from a solar light source,
a polymeric carrier layer (3); and
a polymeric film (1) comprising a first surface embossed with optical structures which form one or more Fresnel lenses, and a second surface bonded to the polymeric carrier layer (3) either directly or via an adhesive layer (2),
wherein
(i) the polymeric carrier layer (3) comprises a UV absorber and a UV stabilizer, or
(ii) an UV protecting polymer layer (5), comprising a UV absorber and a UV stabilizer, is bonded to the solar light source facing a surface of the polymeric carrier layer (3) either directly or via an adhesive layer (4), or
both (i) and (ii).

2. The UV protected laminated solar concentration device according to claim 1,
further comprising: a polymer surface protecting layer (7), wherein
the polymer surface protecting layer (7) is bonded to the solar light source facing a surface of the polymer surface protecting layer (5), either directly or via an adhesive layer (6), or to the solar light source facing the surface of the polymeric carrier layer (3), either directly or via an adhesive, and
the polymer surface protecting layer (7) has at least one of following properties: soil-repellent property, scratch resistance, abrasion resistance-improving property, and anti-reflection property.

3. A process for manufacturing the UV protected laminated solar concentration devices according to claim 1, the process comprising:
coextruding the polymeric carrier layer (3) and the UV protecting layer (5), thereby obtaining a coextrudate of the polymeric carrier layer (3) and the UV protecting layer (5), and
subsequently laminating the polymeric film (1) to a backside of the polymeric carrier layer (3), with or without the adhesive layer (2).

4. The process according to claim 3,
wherein said laminating the polymeric carrier layer (3) and the polymeric film (1) without the adhesive layer (2) comprising:
a obtaining the polymeric film (1);
guiding the polymeric film (1) to a nip point of a pair of lamination rolls;
feeding the coextrudate of the polymeric carrier layer (3) and the UV protecting polymer layer (5) to the nip point, wherein a surface of the polymeric carrier layer (3), intended to be bonded to the polymeric film (1), has a surface temperature suitable for thermal bonding between the polymeric carrier layer (3) and the polymeric film (1); and
laminating the polymeric carrier layer (3) to the second surface of the polymeric film (1).

5. The UV protected laminated solar concentration device according to claim 1,
wherein
the polymeric film (1) comprises an imposed square or rectangular Fresnel lens pattern, or a matrix of square individual Fresnel lenses arranged in a grid pattern, or
the polymeric film (1) is configured as a linear Fresnel lens where a Fresnel lens pattern is continuous for a total length of the polymeric film (1).

6. The UV protected laminated solar concentration device according to claim 1,
wherein the adhesive layer (2) is a solvent cement.

7. The UV protected laminated solar concentration device according to claim 1,
wherein the polymeric film (1) comprises at least one polymer selected from the group consisting of poly(meth)acrylate, polycarbonate, a cyclic olefin polymer, polystyrene, polyvinylidenedifluoride, a polyurethane, and a copolymer thereof,
the polymeric carrier layer (3) is a polycarbonate, polystyrene, a styrene copolymer, a polyester, a fluoropolymer, a PMMA based film or sheet, a two-layer PMMA/PVDF film or sheet, or a film or sheet of a PMMA/PVDF blend, or
the UV protecting polymer layer (5) consists of a transparent single- or multilayer plastics foil, wherein at least one layer comprises polymethyl (meth)acrylate or a mixture of polymethyl (meth)acrylate and polyvinylidene fluoride.

8. The UV protected laminated solar concentration device according to claim 1,
wherein the polymeric carrier layer (3), the UV protecting polymer layer (5), or both comprise a mixture of UV absorbers, and a UV stabilizer,
the UV absorbers comprise a triazine UV absorber and a benzotriazole UV absorber, and
the UV stabilizer comprises a HALS compound or a mixture of various HALS compounds.

9. The UV protected laminated solar concentration device according to claim 8, wherein the mixture comprises, based on a total weight of monomers used to prepare the polymer carrier layer (3) or the UV protecting polymer layer (5):
from 0.1% to 10% by weight, of the benzotriazole UV absorber,
from 0.1% to 5% by weight, of the triazine UV absorber, and
from 0.1% to 5% by weight, of the HALS compound or the mixture of various HALS compounds.

10. The UV protected laminated solar concentration device according to claim 1,
wherein
the UV protecting polymer layer (5) comprises poly(meth)acrylate and polyvinylidene fluoride in a ratio by weight of from 1:0.01 to 0.3:1,
or
the UV protecting polymer layer (5) comprises a first sublayer comprising poly(meth)acrylate and a second sublayer comprising polyvinylidene fluoride.

11. The UV protected laminated solar concentration device according to claim 1,
wherein
the polymeric film (1) has a thickness of from 0.01 to 10 mm,
the polymeric carrier layer (3) has a thickness of from 0.1 mm to 50 mm, or
the UV protecting polymer layer (5) has a thickness of from 10 to 250 μm.

12. The UV protected laminated solar concentration device according to claim 1,
wherein
the polymeric carrier layer (3) comprises a heat stabilizer.

13. A solar device,
wherein the solar device is
a CPV element comprising at least one of the solar concentration device according to claim 1 and a solar cell, or
a CSP element comprising at least one of the solar concentration device according to claim 1 and a heat absorbing element.

14. A method for producing a solar thermic device or a photovoltaic device, comprising:
introducing the UV protected laminated solar concentration device according to claim 1 into a solar thermic device or a photovoltaic device in need thereof.

15. A process for manufacturing the UV protected laminated solar concentration devices according to claim 1, the process comprising:
laminating the polymeric carrier layer (3) and the UV protecting layer (5) via extrusion lamination, with or without the adhesive layer (4), and
subsequently laminating the polymeric film (1) to a backside of the polymeric carrier layer (3), with or without the adhesive layer (2).

16. A process for manufacturing the UV protected laminated solar concentration devices according to claim 1, the process comprising:
laminating the polymeric carrier layer (3) and the polymeric film (1), with or without the adhesive layer (2), and
subsequently laminating the UV protecting layer (5) to the solar light source facing the surface of the polymeric carrier layer (3), with or without the adhesive layer (4).

17. A process for manufacturing the UV protected laminated solar concentration devices according to claim 1, the process comprising:
laminating the polymeric carrier layer (3), comprising a UV absorber and a UV stabilizer, and the polymeric film (1), with or without the adhesive layer (2).
